(19) United States
(12) Patent Application Publication
(10) Pub. No.: US 2009/0032090 A1
(43) Pub. Date: Feb. 5, 2009

(54) METHOD FOR ASSEMBLING A TERRESTRIAL SOLAR ARRAY INCLUDING A RIGID SUPPORT FRAME

(75) Inventors: MIKHAIL KATS, Rockaway, NJ (US); SCOTT ELMAN, Monroe Township, NJ (US); GARY HERING, Belle Mead, NJ (US); ALAN GORENZ, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/200,168

(22) Filed: Aug. 28, 2008

Related U.S. Application Data
(63) Continuation-in-part of application No. 12/131,556, filed on Jun. 2, 2008.
Application No. 12/131,556 is a continuation-in-part of application No. 11/830,636, filed on Jul. 30, 2007, now Pat. No. 7,381,886.

(51) Int. Cl. H01L 31/042

(52) U.S. Cl. 136/251

(57) ABSTRACT

A method for assembling a concentrator photovoltaic solar cell array system for producing energy from the sun includes installing a foundation on a surface and coupling a central support to the foundation. A cross member is coupled to the central support and one or more inclined arms are coupled to the cross member and the central support. A support frame, which includes a first frame assembly arranged to couple to one or more solar cell subarrays, is coupled to the cross member. One or more solar cell subarrays are coupled to the first frame assembly thereby forming a solar cell array, wherein each solar cell subarray includes a plurality of triple junction III-V semiconductor compound solar cell receivers. To enable rotation of at least a portion of the central support coupled to the support frame, an actuator is installed.

### REFERENCE TO RELATED APPLICATIONS

This application is a continuation-in-part application of and claims priority to U.S. patent application Ser. No. 12/131,556, filed on Jun. 2, 2008, which is a continuation-in-part application of U.S. application Ser. No. 11/830,636, filed on Jul. 30, 2007, now U.S. Pat. No. 7,381,886, each of which is incorporated herein by reference. This application is related to co-pending U.S. application Ser. No. 12/024,489 filed Feb. 1, 2008, which is a divisional of U.S. application Ser. No. 11/830,636.

This application is also related to co-pending U.S. patent application Ser. No. 11/500,053 filed Aug. 7, 2006, and U.S. patent application Ser. No. 11/849,033 filed on Aug. 31, 2007 by the common assignee.

### BACKGROUND

This disclosure relates generally to a method of assembling a terrestrial solar array including a rigid support frame. A solar array can be implemented as part of a terrestrial solar power system for the conversion of sunlight into electrical energy and can include III-V compound semiconductor solar cells. Compound semiconductor solar cells, based on III-V compounds, have 28% efficiency in normal operating conditions. Moreover, concentrating solar energy onto a III-V compound semiconductor photovoltaic cell can increase the cell's efficiency to over 37%. Aspects of a solar cell system include the specification of the number of cells used to make up an array, and the shape, aspect ratio, and configuration of the array.

One aspect of a solar cell system is the physical structure of the semiconductor material layers constituting the solar cell. Solar cells are often fabricated in vertical, multijunction structures to utilize materials with different bandgaps and convert as much of the solar spectrum as possible. One type of multijunction structure is the triple junction solar cell structure consisting of a germanium bottom cell, a gallium arsenide (GaAs) middle cell, and an indium gallium phosphide (InGaP) top cell.

In the design of both silicon and III-V compound semiconductor solar cells, one electrical contact is typically placed on a light absorbing or front side of the solar cell and a second contact is placed on the back side of the cell. A photoactive semiconductor is disposed on a light-absorbing side of the substrate and includes one or more p-n junctions, which creates electron flow as light is absorbed within the cell. Grid lines extend over the top surface of the cell to capture this electron flow which then connect into the front contact or bonding pad.

The individual solar cells are typically disposed in horizontal arrays, with the individual solar cells connected together in electrical series. The shape and structure of an array, as well as the number of cells it contains, and the sequence of electrical connections between cells are determined in part by the desired output voltage and current of the system.

Another aspect of terrestrial solar power systems is the use of light beam concentrators (such as lenses and mirrors) to focus the incoming sunrays onto the surface of a solar cell or solar cell array. The geometric design of such systems also requires an appropriate solar tracking mechanism, which allows the plane of the solar cells to continuously face the sun as the sun traverses the sky during the day, thereby optimizing the amount of sunlight impinging upon the cell.

Accurate solar tracking is advantageous because the amount of power generated by a given solar cell is related to the amount of sunlight that impinges on it. In an array, therefore, it is advantageous to optimize the amount of sunlight that impinges on each constituent solar cell. For example, misalignment of about one degree can appreciably reduce efficiency. Because arrays are often mounted outdoors and are large, heavy structures, this presents challenges. Even moderate wind can cause bending and the array can bend under its own weight. These problems are usually most pronounced in regions near the perimeter of the array. As a result, the solar cells that are disposed in the regions where bending occurs can become misaligned with the sun, compromising power generation.

### SUMMARY

The invention relates to a method of assembling a terrestrial solar array including a rigid support frame.

In some implementations, a method for assembling a concentrator photovoltaic solar cell array system for producing energy from the sun includes installing a foundation on a surface and coupling a central support to the foundation. A cross member is coupled to the central support, and one or more inclined arms are coupled to the cross member and the central support to provide, for example, structural support for the cross member. A support frame, which includes a first frame assembly arranged to couple to one or more solar cell subarrays, is coupled to the cross member. One or more solar cell subarrays are coupled to the first frame assembly thereby forming a solar cell array, wherein each solar cell subarray includes a plurality of triple junction III-V semiconductor compound solar cell receivers. To enable rotation of at least a portion of the central support coupled to the support frame, an actuator is installed.

In some implementations, a method for assembling a concentrator photovoltaic solar cell array system for producing energy from the sun includes installing a foundation on a surface, coupling a central support to the foundation, and coupling a support frame to the central support member. The support frame includes a first frame assembly arranged to couple to one or more solar cell subarrays. A second frame assembly is provided to couple to the first frame assembly to increase the rigidity of the first frame assembly. One or more solar cell subarrays are coupled to the first frame assembly, thereby forming a solar cell array. Each solar cell subarray includes a plurality of triple junction III-V semiconductor compound solar cell receivers. To enable rotation of at least a portion of the central support coupled to the support frame, an actuator is installed.

Some implementations provide one or more of the following features and advantages. For example, the method can provide an improved solar cell array utilizing a III-V compound semiconductor multijunction solar cells for terrestrial power applications. A second frame assembly can be coupled orthogonally to the first frame assembly, and arranged to increase the rigidity of the first frame assembly. The second frame assembly can include a truss. The solar cell subarrays can be coupled to the first frame assembly such that the second frame assembly is mounted above the vertical center of the solar cell array. Coupling the cross member to the central support can occur before the coupling the cross member to the central support. The support frame can be provided in two halves that are assembled. A jackscrew can be installed, wherein installing the jackscrew includes coupling the jackscrew to the cross member and the support frame. The first frame assembly can be coupled such that it is arranged along the greatest perpendicular dimension of the solar cell array. The second frame assembly can be coupled such that it is arranged along the greatest perpendicular dimension of the solar cell array. The first frame assembly can comprise ten mounting positions, each arranged to receive a solar cell subarray. The ten mounting positions can be sequentially ordered from one end of the first frame assembly to the opposite end of the first frame assembly, and the coupling the solar cell subarrays to the first frame assembly can include, in the order set forth, installing a first solar cell subarray at a fifth mounting position; installing a second solar cell subarray at a sixth mounting position; installing a third solar cell subarray at a fourth mounting position; installing a fourth solar cell subarray at a seventh mounting position; installing a fifth solar cell subarray at a third mounting position; installing a sixth solar cell subarray at an eighth mounting position; installing a seventh solar cell subarray at a second mounting position; installing an eighth solar cell subarray at a ninth mounting position; installing a ninth solar cell subarray at a first mounting position; and installing a tenth solar cell subarray at a tenth mounting position. Increasing the rigidity of the first frame assembly can comprise preventing a deflection greater than 1 degree near the perimeter of the solar cell array. Coupling the support frame to the central support member can comprise coupling a cross member to the central support and coupling the support frame to the cross member.

Other features and advantages will be readily apparent from the detailed description, accompanying drawings and the claims.

### BRIEF DESCRIPTION OF THE DRAWINGS

FIG. 1A is a perspective view of an implementation of a terrestrial solar cell system.

FIG. 1B is a second perspective view of the implementation of FIG. 1A.

FIG. 1C is a perspective view of an implementation of a terrestrial solar cell system.

FIG. 1D is a perspective view of an implementation of a support frame for use with the terrestrial solar cell system of FIG. 1C.

FIG. 1E is a simplified side view of an implementation of a terrestrial solar cell system.

FIG. 1F is a side view of an implementation of a terrestrial solar cell system.

FIG. 2 is a perspective view of the solar cell system implementation of FIG. 1A viewed from the opposite side thereof.

FIG. 3 is a perspective view of a portion of an implementation of a solar cell subarray utilized in a terrestrial solar cell system.

FIG. 4 is a perspective view of an implementation of a solar cell receiver utilized in a solar cell subarray.

FIG. 5 is a top plan view of a single solar cell subarray.

FIG. 6A is an implementation of a method for assembling a terrestrial solar array including a rigid support frame.

FIGS. 6B-6H illustrate additional details of the implementation of FIG. 6A.

Additional advantages and features will become apparent to those skilled in the art from this disclosure, including the following detailed description. While the invention is described below with reference to implementations thereof, the invention is not limited to those implementations. Those of ordinary skill in the art having access to the teachings herein will recognize additional applications, modifications and implementations, which are within the scope of the invention as disclosed and claimed herein and with respect to which the invention could be of utility.

### DETAILED DESCRIPTION

### Overview

A terrestrial solar power system converts sunlight into electrical energy utilizing, e.g., multiple mounted arrays spaced in a grid over the ground. The array of solar cells has a particular optical size and aspect ratio (e.g., between 1:3 and 1:5), and is mounted for unitary movement on a cross-arm of a vertical support that tracks the sun. The array can include subarrays, sections, modules and/or panels.

The solar tracking mechanism allows the plane of the solar cells to continuously face the sun as the sun traverses the sky during the day, thereby optimizing the amount of sunlight impinging upon the cells. The amount of power generated by the array is directly related to the amount of sunlight impinging upon the constituent solar cells. Since a given array can comprise many (e.g., a thousand or more) solar cells, it is advantageous to maintain the solar alignment of the entire array. This, however, is difficult in practice because it is not uncommon for an array to be upwards of 18 meters wide (about 59 feet) and 7.5 meters high (about 25 feet). Given the size of the array, solar cells near the perimeter may become misaligned due to bending or flexing of the array. Bending or flexing can arise, e.g., as a result of wind or the weight of the array causing the structure to bend. Since misalignment as little as one degree or less is detrimental in some implementations, it is desirable to minimize bending or flexing of the array.

### Implementations of a Terrestrial Solar Cell System

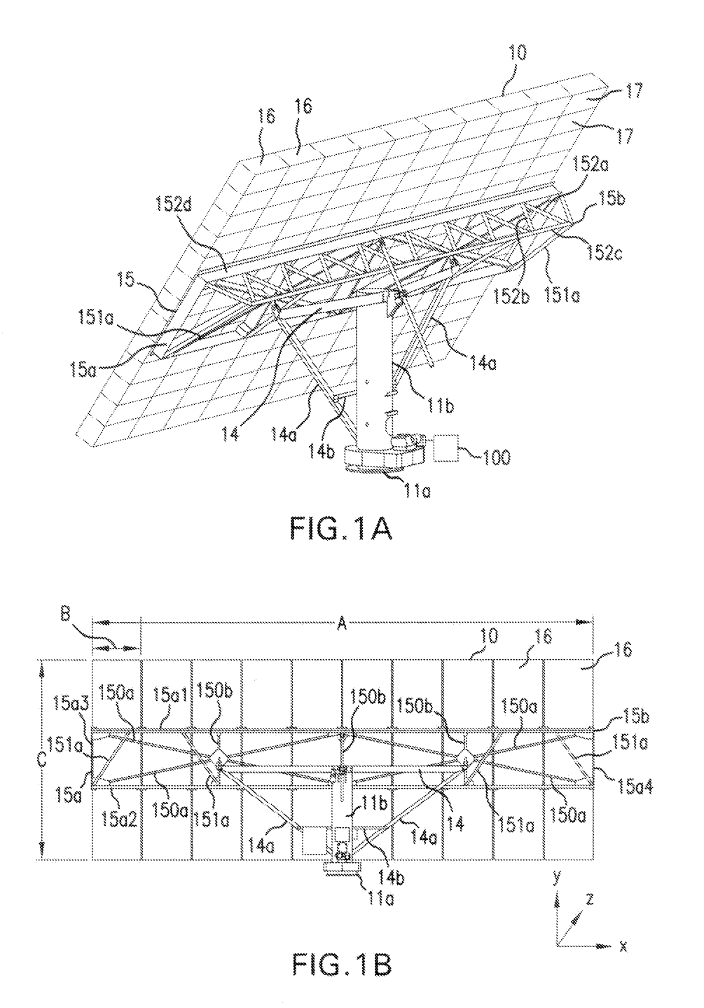

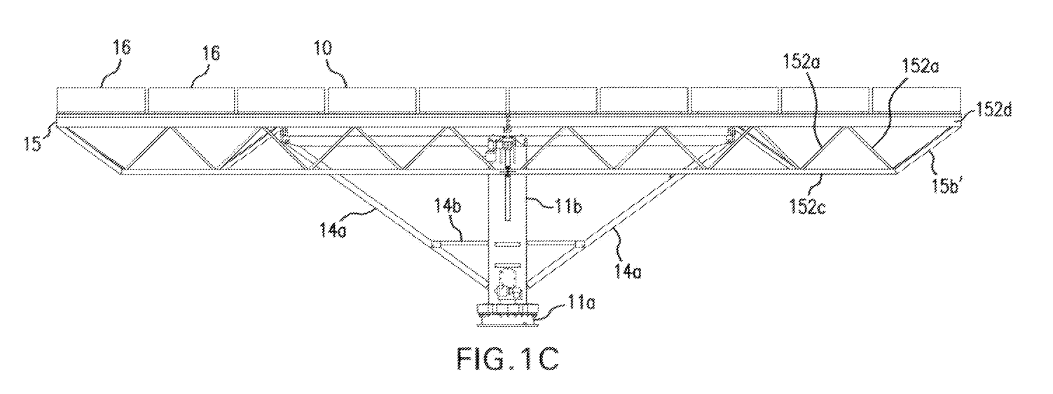

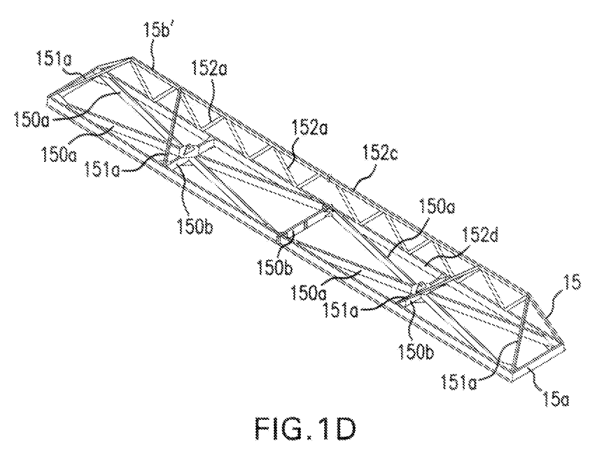

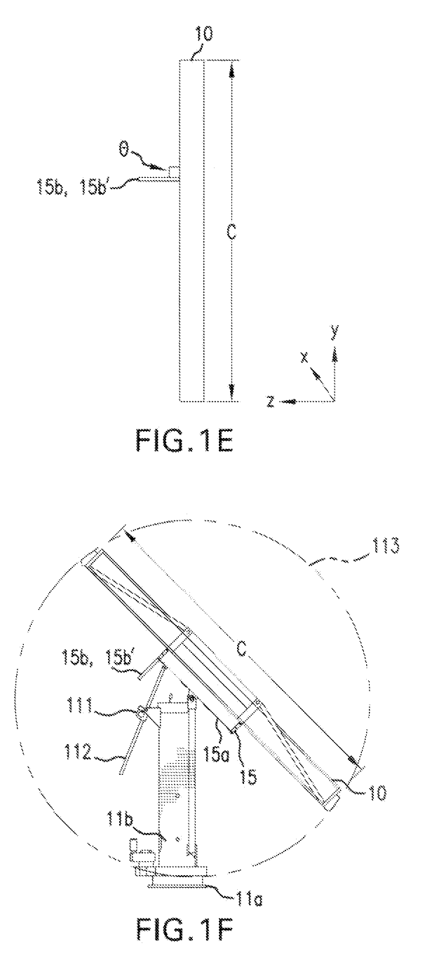

An implementation of a terrestrial solar cell system is illustrated in FIG. 1A. In general terms, the system comprises three major components. The first major component is the central support (11a and 11b). The central support is mounted to a surface and is capable of rotating about its longitudinal axis. Depending on the implementation, the surface can be, e.g., the ground or a concrete foundation formed in the ground. Disposed on or adjacent to the surface is a drive mechanism 100 (e.g., a gearbox) that couples to the central support. The drive mechanism 100 enables the inner member 11b to rotate relative to the outer member 11a, e.g., for moving the solar cell array such that it tracks the sun.

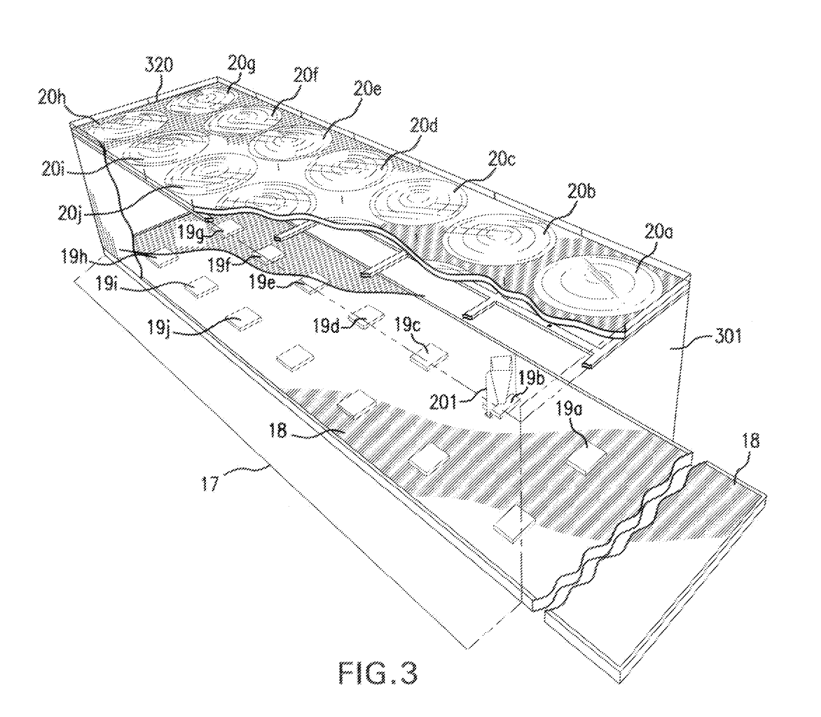

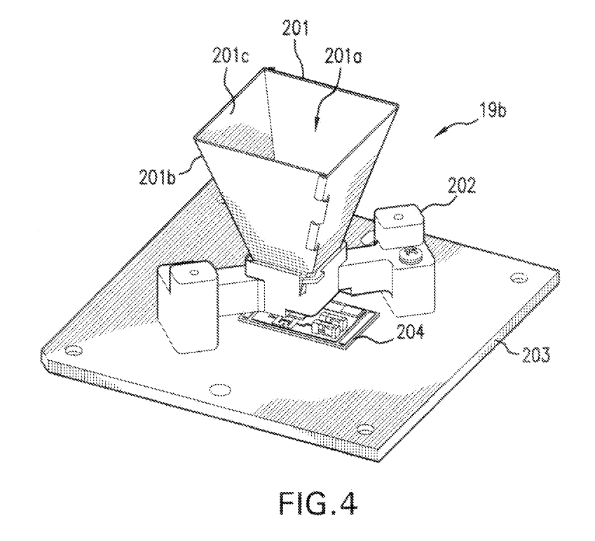

The second major component is the support frame 15. The support frame 15 couples to the central support and is adapted to support a solar cell array (e.g., array 10). The third major component is the solar cell array 10. The solar cell array 10 includes multiple subarrays or panels 16 and is coupled to, and supported by, the support frame 15. The solar cell array 10 converts sunlight into electricity, and normally is kept facing the sunlight by the rotation of the central support. In this implementation, each of the solar cell subarrays 16 is divided into thirteen sections 17. Each section 17 includes a 2×7 panel of concentrating lenses (e.g., item 320 of FIG. 3) each lens disposed over a single receiver (e.g., item 19b of FIGS. 3 and 4). The receiver, a printed circuit or subassembly, includes a single III-V compound semiconductor solar cell together with additional circuitry such as a bypass diode (not shown). In some implementations, each section 17 is a module, e.g., a discrete assembly. In some implementations, the sections 17 are separated from each other by perforated dividers.

In the illustrated implementation, the central support includes an outer member 11a and an inner member 11b. The outer member 11a is connectable to a support mounted on the surface by bolts. The inner member 11b is rotatably mounted within the member 11a and supports a cross member 14 which is connected to a support frame 15. The support frame 15 also is supported on the inner member 11b by a pair of inclined arms 14a which extend respectively from two of the support struts 150b (visible in FIG. 1B) to the base of the inner member 11b. The inclined arms 14a are coupled to each other by a cross-member 14b (see also FIG. 1B) that increases their structural integrity. The mounting of the support frame 15 in this manner ensures that it is fixed to the inner member 11b of the central support in such a manner that it is rotatable about its central longitudinal axis through members 11a and 11b.

The support frame 15 has a rectangular frame 15a and a truss 15b. The rectangular frame 15a includes two shorter members (see items 15a3 and 15a4 of FIG. 1B) that are oriented in a direction parallel to the height (see dimension “C” of FIG. 1B) of the solar cell array 10 and two longer members (see items 15a1 and 15a2 of FIG. 1B) that are oriented in a direction parallel to the width (see dimension “A” of FIG. 1B) of the solar cell array 10. In this implementation, the width of the rectangular frame 15a is approximately equal to the width of the solar cell array 10. Although this configuration can result in improved rigidity (e.g., less bending of the solar cell array 10 near its perimeter), it is not required. For example, to reduce material cost, the width of the rectangular frame 15a can be reduced.

The truss 15b is coupled to the rectangular frame 15a in a manner that increases the rigidity of the rectangular frame 15a, and thus, the rigidity of the solar cell array 10. The truss, therefore, improves alignment of the constituent solar cells (particularly those near the perimeter) such that power generation is substantially improved. The truss 15b can function to prevent deflection greater than 1 degree near the perimeter of the solar cell array 10. In some implementations, the truss 15b is aligned with In this implementation, the truss 15b includes a lower truss chord 152d, an upper truss chord 152c, parallel truss brace chords 152b and diagonal truss chords 152a. The parallel truss brace chords 152b and diagonal truss chords 152a are coupled between the upper and lower truss chords 152c and 152d. The parallel truss brace chords 152b are oriented substantially parallel to one another and perpendicular to the upper and lower truss chords 152c and 152d. The particular configuration of chords 152a-d can vary with the implementation. For example, truss 15b may include no diagonal truss chords (e.g., a Vierendeel truss), no parallel truss brace chords (e.g., a lattice truss), or the relative orientation of the diagonal truss chords can vary (e.g., a Pratt truss or a Howe truss).

In this implementation, the truss 15b is coupled to the rectangular frame 15a by truss support members 151a. Also, in this implementation the rectangular frame 15a and truss 15b are integrated, i.e., the lower truss chord 152d comprises one of the longer members of the rectangular frame 15a. In this implementation, the width of the truss 15b (e.g., the width of the lower chord 152d) is approximately equal to the width of the solar cell array 10 and the rectangular frame 15a. Although this configuration can result in improved rigidity (e.g., less bending of the solar cell array 10 near its perimeter), it is not required. For example, to reduce material cost, the width of the truss 15b can be reduced.

In this implementation, the truss 15b is arranged such that the direction of its height (i.e., the perpendicular direction between the lower truss chord 152d and the upper truss chord 152c) is substantially orthogonal to the plane defined by the height and width of the solar cell array 10. Although this configuration can result in improved rigidity, it is not required. For example, to accommodate packaging requirements, the truss 15b can be coupled such that the direction of its height is not substantially orthogonal to the plane defined by the height and width of the solar cell array 10.

In the illustrated implementation, the truss 15b is not disposed in the vertical center (i.e., along dimension “C” of FIG. 1B) of the solar cell array 10. The inventors discovered that placing the truss 15b above the vertical centerline of the solar cell array 10 can result in improved maneuverability with respect to the center support. As a result, the central support can move the solar cell array 10 to track sunlight without interference by the presence of the truss 15b.

Although the illustrated implementation utilizes a truss 15b to increase the rigidity of the rectangular frame 15a, other structures are possible. For example, a solid plate can be used. In another example, a solid plate having one or more cutouts can be used. Moreover, a very simple truss can be used that omits chords 152a and 152b in favor of simply coupling upper truss chord 152c to the lower truss chord 152d. Such a truss can include one or more additional members that are oriented parallel to the upper truss chord 152c.

FIG. 1B is a rear-facing view of the terrestrial solar cell system of FIG. 1A, with the solar cell array 10 oriented orthogonally to the surface to which the central support is mounted (e.g., the ground). As illustrated, the truss 15b aligned along the greatest perpendicular dimension (i.e., along dimension “A”) of the array 10. This is advantageous because the array is generally more prone to bending along a longer axis than along a shorter axis (e.g., along dimension “C”). In this implementation, dimension “A”, the width of the solar cell array 10, is approximately 18.1 meters (approximately 59.4 feet), dimension “B”, the width of subarray 16, is approximately 1.8 meters (approximately 5.9 feet) and dimension “C”, the height of the solar cell array 16, is approximately 7.5 meters (approximately 24.6 feet). Such an implementation has a solar collecting area of approximately 98.95 square meters (approximately 1065.1 square feet) and weighs approximately 10,191 kilograms (approximately 10.03 tons). If constructed in a manner consistent with this disclosure, such an implementation can have a wind survival rating of 145 kilometers/hour (approximately 90.1 miles/hour).

In FIG. 1B, the view of the truss 15b is largely obscured because it is arranged orthogonally to the plane defined by the height and width of the solar cell array. However, this view illustrates truss support members 151a, which couple the truss 15b to the rectangular frame 15a. In particular, the truss support members 151 couple to a long member 15a1 or 15a2 of the rectangular frame 15a (in this implementation, the lower long member 15a2) and the upper truss chord 152c (see FIG. 1A). In this implementation, four truss support members 151a are shown arranged diagonally. While arranging the truss support members 151a diagonally offers the advantage of resisting tension and compression, it is not necessary. Also, more or fewer truss support members 151a can be employed depending on the implementation.

This view also reveals additional features of the rectangular frame 15a. To improve the structural integrity of the rectangular frame, several cross members 150a couple the upper long member 15a1 to the lower longer member 15a2. The cross members 150a are complemented by parallel members 150b (which, in this implementation, are oriented substantially parallel to the shorter members 15a3 and 15a4). Two of the parallel members 150b serve the additional purpose of providing a mounting point to which the cross member 14 couples.

This view again illustrates that the width of the rectangular frame 15a is approximately the same width as the solar cell array 10 (i.e., it is about 18.1 meters wide). This view also illustrates that the location of the truss 15b is above the centerline of dimension C.

FIG. 1C illustrates an implementation of a terrestrial solar cell system with the plane defined by the height and width of the solar cell array 10 oriented parallel to the surface to which the central support is mounted (e.g., the ground). This implementation utilizes a truss 15b′ having a configuration slightly different than that of 15b. This truss 15b′ omits parallel truss brace chords 152b in favor of using all diagonal truss chords 152a. FIG. 1D illustrates a perspective view of a support frame 15 comprising truss 15b′.

FIG. 1E is simplified view of a terrestrial solar cell system, viewed from a direction orthogonal to the plane defined by the height and width of the solar cell array 10. As illustrated, the truss (15b or 15b′ depending on the implementation) is disposed above the centerline of dimension C. Also, the truss (15b or 15b′) in this implementation is oriented at a right angle (θ) relative to the solar cell array 10.

FIG. 1F is a side view of an implementation of a terrestrial solar cell system, viewed from a direction orthogonal to the plane defined by the height and width of the solar cell array 10. As illustrated, the truss (15b or 15b′ depending on the implementation) is disposed above the centerline of dimension C. By locating the truss above the vertical center of the solar cell array, the truss does not obstruct movement of the array relative to the central support (11a, 11b). Jackscrew 111 and mating threaded rod 112 together can adjust the angle (or inclination) of the array 10 through at least a portion of the range indicated by path 113. Thus, the jackscrew 111 (e.g., in combination with a drive mechanism such as item 100 of FIG. 1A) enables pivoting the support frame 15, and thus the array 10, so as to adjust its angle with respect to the earth's surface

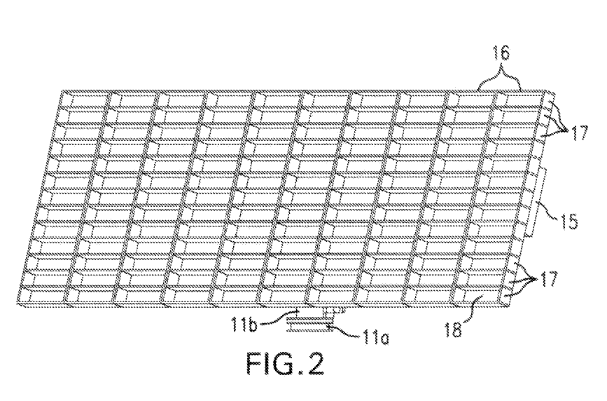

FIG. 2 is a perspective view of the solar cell system implementation of FIG. 1A viewed from the opposite side thereof. This perspective illustrates the division of each subarray 16 into sections 17. Each section 17 includes a base 18, which provides a structural foundation for each receiver 19 (see FIGS. 3 and 4). In some implementations, there is one base 18 per subarray 16, shared by each constituent section 17. In some implementations, the base 18 is structurally distinct for each section 17.

FIG. 3 is a cutaway view of a solar cell subarray 16 depicting one section 17 on base 18. In this implementation, section 17 includes a sheet 320 including a 2×7 matrix of Fresnel lenses (20a-20j are shown), a 2×7 matrix of secondary optical elements (“SOE”, an example of which is shown as item 201) and a 2×7 matrix solar cell receivers 19 (fourteen are shown, including items 19a-19j). In some implementations, the sheet 320 is an integral plastic panel and each Fresnel lens (e.g., items 20a-20j) is a nine-inch square. In the illustrated implementation, each Fresnel lens (e.g., 20b) and its associated receiver (e.g., 19b) and SOE (e.g., 201) are aligned such that the light concentrated by the lens is optimally received by the solar cell of the associated receiver. In the illustrated implementation, section 17 is delineated from the remainder of the base 18 by a divider 301 (which can be perforated). The base 18 also which serves to dissipate heat from the receivers, and more particularly from the individual solar cells.

FIG. 4 illustrates a receiver 19b in more detail. The receiver 19b has a plate 203, a printed circuit board (“PCB”) 204, an SOE 201 and a mount 202. The plate 203 couples the receiver 19b to the base 18 (see FIGS. 2 and 3). In some implementations, the plate 203 is constructed of a material having a high thermal conductivity such that the heat from the PCB 204 (which includes, for example, a solar cell and a bypass diode) is dissipated away efficiently. In some implementations, the plate 203 is made of aluminum. In some implementations, the PCB 204 includes a ceramic board with printed electrical traces.

The mount 202, which is coupled to the plate 203 at two positions, forms a bridge that aligns the SOE 201 with the solar cell of the PCB 204. The SOE 201 gathers the light from its associated lens 20 and focuses it into the solar cell on the PCB 204. In some implementations, each solar cell receiver 19 is provided with a corresponding SOE 201. The SOE 201 includes an optical inlet 201a and optical outlet (facing the PCB 204) and a body 201b. The SOE 201 is mounted such that the optical outlet is disposed above the solar cell of the PCB 204. Although it can vary depending on the implementation, the SOE 201 in the illustrated example is mounted such that the optical outlet is about 0.5 millimeters from the solar cell. The SOE 201 (including the body 201b) can be made of metal, plastic, or glass or other materials.

In some implementations, the SOE 201 has a generally square cross section that tapers from the inlet 201a to the outlet. The inside surface 201c of the SOE reflects light downward toward the outlet. The inside surface 201c is, in some implementations, coated with silver or another material for high reflectivity. In some cases, the reflective coating is protected by a passivation coating such as SiO2 to protect against oxidation, tarnish or corrosion. The path from the optical inlet 201a to the optical outlet forms a tapered optical channel that catches solar energy from the corresponding lens 20 and guides it to the solar cell. As shown in this implementation, the SOE 201 has four reflective walls. In other implementations, different shapes (e.g., three-sided to form a triangular cross-section) may be employed.

In some cases, the corresponding lens 20 does not focus light onto a spot that is of the dimensions of the solar cell or the solar tracking system may not perfectly point to the sun. In these situations, some light does not reach the solar cell. The reflective surface 201c directs light to the solar cell 30. The SOE also can homogenize (e.g., mix) light. In some cases, it also has some concentration effect.

In some implementations, the optical inlet 201a is square-shaped and is about 49.60 mm×49.60 mm, the optical outlet is square-shaped and is about 9.9 mm×9.9 mm and the height of the optical element is about 70.104 mm. These dimensions can vary with the design of the solar cell module, section and/or the receiver. For example, in some implementations the dimensions of the optical outlet are approximately the same as the dimensions of the solar cell. For an SOE having these dimensions, the half inclination angle is 15.8 degrees.

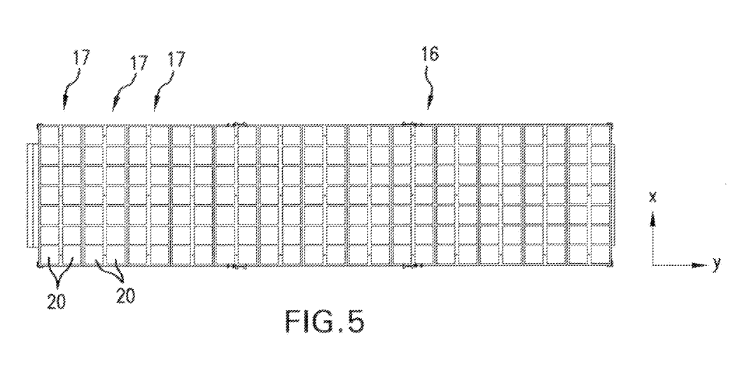

In a particular implementation, as illustrated in the plan view of FIG. 5, the subarray 16 is about 7.5 meters high (y direction) and 1.8 meters wide (x direction) and includes sections 17 each having a 2×7 matrix of Fresnel lenses 20 and receivers 19 (see FIGS. 3 and 4). Each receiver 19 produces over 13 watts of DC power on full AM 1.5 solar irradiation. The receivers are connected by electrical cables in parallel or in series so that the aggregate 182 receivers in an entire subarray 16 can produce in excess of 2500 watts of peak DC power. Each of the subarrays is in turn connected in series, so that a typical array (e.g., item 10) can produce in excess of 25 kW of power.

A motor provides drive to rotate the member 11b relative to the member 11a, and another motor provides drive to rotate the cross member 14 (and hence the support frame 15) relative to the central support 11 about its longitudinal axis. Control means are provided (e.g., disposed in drive mechanism 100 of FIG. 1) for controlling rotation of the member 11b relative to the member 11a, and for controlling rotation of the cross member 14 (and the support frame 15) about its axis to ensure that the planar exterior surface of each of the sections 17 comprising Fresnel lenses 20 is orthogonal to the sun's rays. In some implementations, the control means is a computer controlled machine, using software that controls the motors in dependence upon the azimuth and elevation of the sun relative to the system. In some implementations, each of the Fresnel lenses 20 concentrates incoming sunlight onto the solar cell in an associated receiver (e.g., item 19b) by a factor of over 500×, thereby enhancing the conversion of sunlight into electricity with a conversion efficiency of over 37%. In some implementations, the concentration is 520×.

In some implementations, the system is refractive and uses an acrylic Fresnel lens to achieve 520× concentration with an f# of approximately 2. A reflective secondary optical element can be used, as described in connection with FIG. 4. An acceptance angle for an individual cell/optics system is ±1.0 degrees. The efficiency of the optical system on-sun is 90% with the acceptance angle defined at a point where the system efficiency is reduced by no more than 10% from its maximum. Some implementations, however, may define a different acceptance angle, e.g. ±0.1 degrees. In some implementations, each solar cell is assembled in a ceramic package that includes a bypass diode and a two spaced-apart connectors. In some implementations, 182 cells are configured in a subarray. The number of cells in a subarray are specified so that at maximum illumination, the voltages added together do not exceed the operational specifications of the inverter.

Additional details of an example of the design of the receiver are described in U.S. patent application Ser. No. 11/849,033 filed Aug. 31, 2007, incorporated herein by reference.

Additional details of an example of the design of the semiconductor structure of the triple junction III-V compound semiconductor solar cell receiver (e.g., item 19) are described in U.S. application Ser. No. 12/020,283, filed Jan. 25, 2008, incorporated herein by reference.

In the illustrated example, the solar cell is a triple junction device, with the top junction based on InGaP, the middle junction based on GaAs, and the bottom junction based on Ge. Typical band-gaps for the cell are 1.9 eV/1.4 eV/0.7 eV, respectively. Typical cell performance as a function of temperature indicate that Voc changes at a rate of −5.9 mV/C and, with respect to temperature coefficient, the cell efficiency changes by −0.06%/C absolute.

One electrical contact is typically placed on a light absorbing or front side of the solar cell, and a second contact is placed on the back side of the cell. A photoactive semiconductor is disposed on a light-absorbing side of the substrate and includes one or more p-n junctions, which creates electron flow as light is absorbed within the cell. Grid lines extend over the top surface of the cell to capture this electron flow which then connect into the front contact or bonding pad. It is advantageous to maximize the number of grid lines over the top surface of the cell to increase the current capacity without adversely interferring with light transmission into the active semiconductor area.

### Implementations of a Method for Assembling a Terrestrial Solar Cell Array

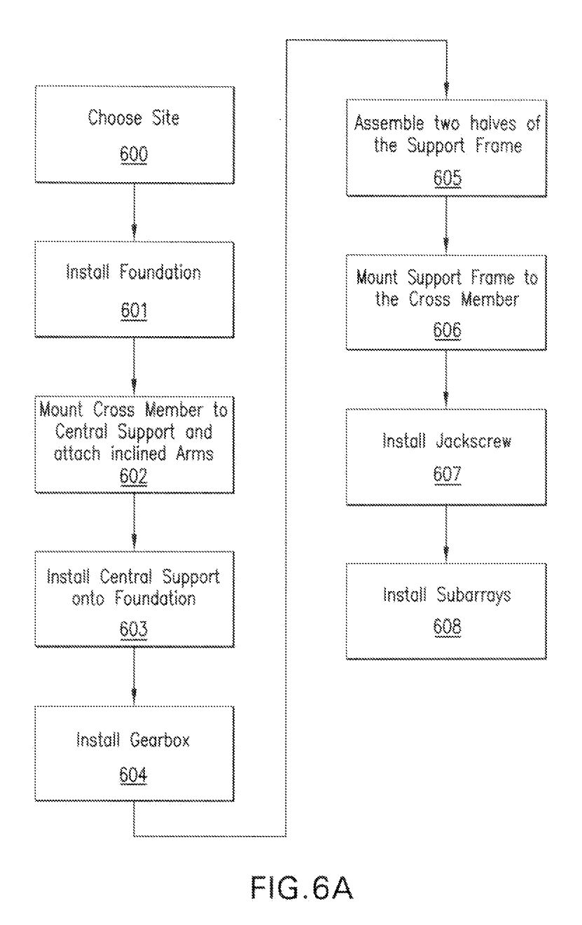

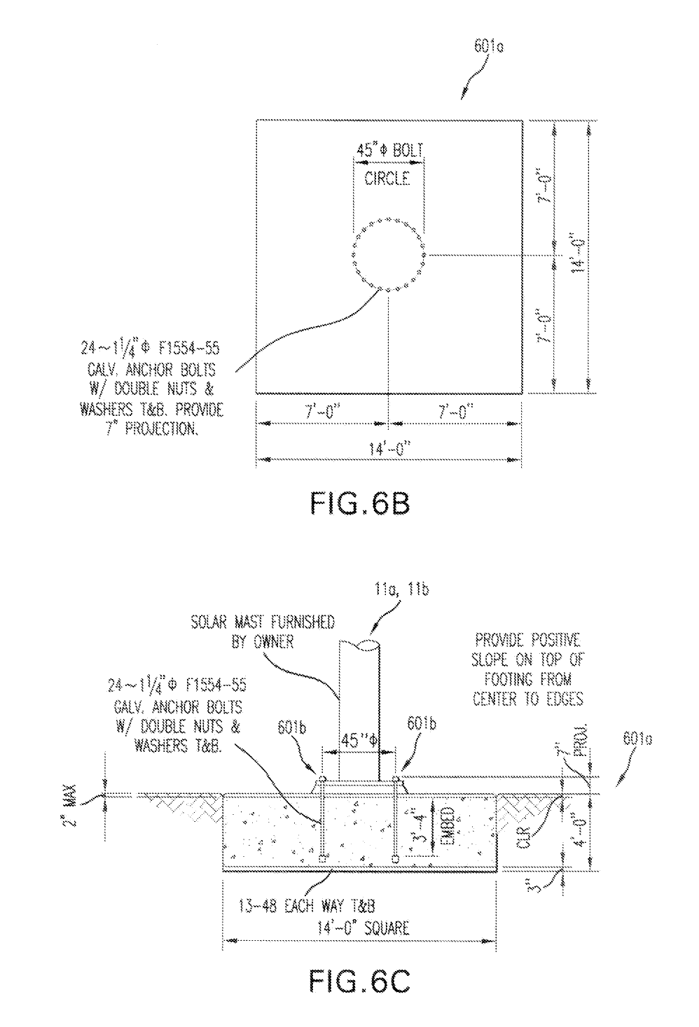

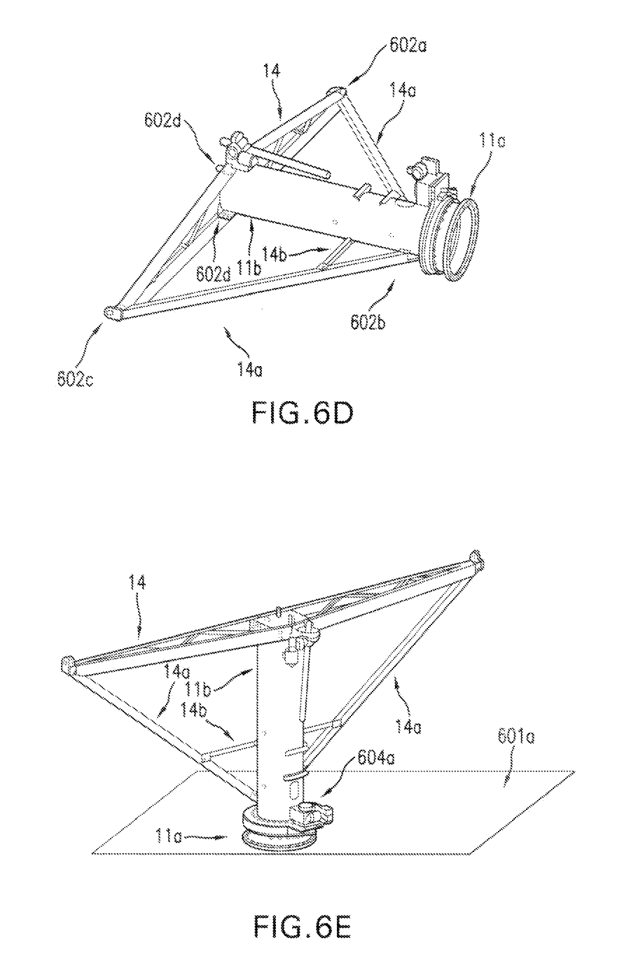

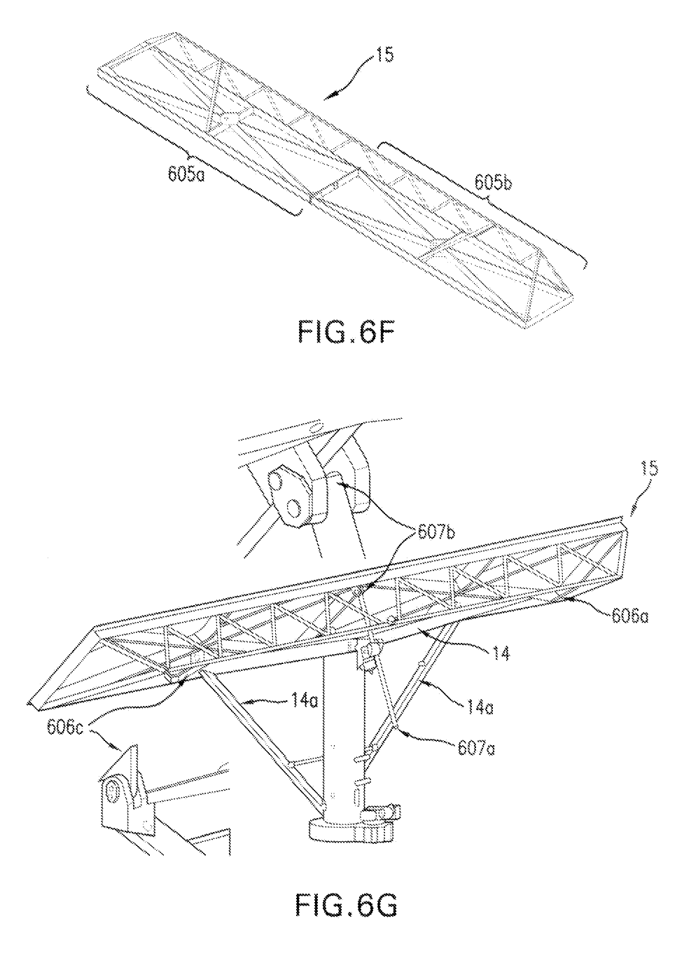

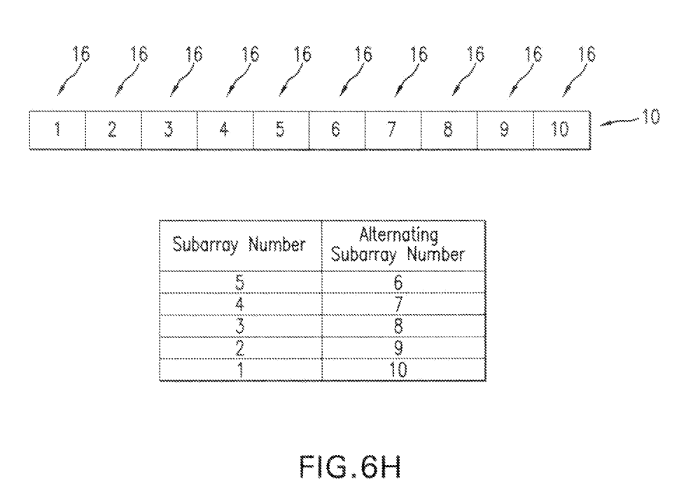

FIG. 6A illustrates an implementation of a method for assembling a terrestrial solar cell array (e.g., the implementation of FIG. 1C). Before assembly begins, however, the site at which the array will be installed is chosen (600). Several factors can be useful in the site selection process. For example, the factors can include one of more of the following:

| Factor | Details |
|---|---|
| Light and | Maximum light exposure is advantageous. It is |
| Shadow Exposure | advantageous if there are no shadows from |
| | surrounding vegetation, structures, or geologic |
| | formations. Surrounding mountains, ridges, or |
| | other geographical obstructions can cast |
| | shadows during the day. It is advantageous to |
| | avoid locations near elements that may cast |
| | shadows in the early morning or late evening. |
| Wind Exposure | It is generally desirable that the site location |
| | have winds of less than 40 kilometers per hour |
| | (25 mph) throughout out the year. In some |
| | implementations, winds in excess of 40 kph |
| | cause the array to go into a stow position while |
| | in tracking mode to avoid possible wind |
| | damage. In some implementations, the stow |
| | position prevents solar energy collection. |
| Temperature | In some implementations, it is desirable to |
| | avoid temperatures in excess of 60° C. (140° F.) |
| | or below −4.4° C. (−40° F.). |
| Water Supply | Water is useful for cleaning the subarray |
| | lenses. In some implementations, either |
| | deionized water or reverse osmosis water is |
| | preferred for cleaning and rinsing. Proper |
| | disposal facilities for the waste water (which |
| | may include a cleaning solution) is advantageous. |
| Internet Access | Internet access is advantageous for terrestrial |
| | solar systems that include, e.g., |
| | communications and operating systems that |
| | allow remote monitoring and control. |
| Soil Composition | The soil composition of a site can affect the |
| | accessibility and cost of installation. The array |
| | foundation or base and support equipment can |
| | be modified as needed to harmonize with the |
| | soil type. However, it is advantageous to avoid |
| | soil prone to erosion and instability if possible. |
| Topography | The proper grade and slope of a potential solar |
| | array site is important for maximum |
| | productivity. Land that requires minimal |
| | grading is generally preferred. It is |
| | advantageous if storm-water discharge has |
| | adequate routes for drainage around or away |
| | from the solar array equipment. |
| Transmission and | Distance from the solar array site to the closest |
| Interconnection | distribution line or substation can affect cost of |
| | installation. Cost of right-of-way |
| | considerations to facilitate transport, and/or |
| | road access should are relevant to the cost |
| | calculation. To interconnect with the power |
| | grid, local utility authorities may require a |
| | system impact study, facilities study, and |
| | transmission service request. |
| Road Accessibility | Accessibility to the site by heavy equipment to |
| | deliver the solar array assembly is |
| | advantageous. The more difficult the terrain |
| | for vehicles to traverse, the more costly it is to |
| | deliver equipment. In that regard, the |
| | following considerations for site accessibility |
| | and area requirements are relevant: (1) |
| | improved roads; (2) sufficient road width; (3) |
| | minimal road curves and/or turns and |
| | sufficient space to navigate curves and turns |
| | and (4) minimal overhead obstructions, e.g., |
| | trees or power lines, and the ability to remove |
| | or work around these obstructions. |

Once an appropriate site is chosen, a foundation for an array is installed (601). The foundation can be designed and engineered appropriately for each site. Depending on the conditions at site, additional reinforcement may be required, e.g., as a result of soil composition and topography. FIGS. 6B and 6C illustrate an implementation of a foundation 601a. In this implementation, the foundation 601a is dimensioned to be approximately a 4.26 meter (14 foot) square.

In the implementation illustrated in FIGS. 6B and 6C, the foundation 601a is constructed with cast-in-place concrete, having a compressive strength of at least about 4000 PSI after 28 days curing. In this implementation, exposed edges of concrete have a 1.9 cm (¾ inch) chamfer. The foundation 601a can include reinforcing steel fabricated and placed in accordance with International Building Code requirements and the Standard Manual (e.g., ACI 315-99). Anchor bolts 601b, which are embedded in the foundation 601a, can be ASTM F1554 Grade 55 (or equivalent) with ASTM A563 heavy hex nuts and ASTM A436 washers. In some implementations, bolts, nuts, and washers are hot-dipped galvanized.

As shown in FIG. 6A, the next block (602) is mounting the cross member 14 to the central support (11a, 11b) and attaching the inclined arms 14a. As shown in FIG. 6D, the cross member 14 is attached to the inner member 11b with bolts 602d. The inclined arms 14a attach at one end to opposite ends of the cross member 14 via attachment points 602a and 602c. Attachment points 602a and 602c can include, e.g., a nut and bolt combination. The other end of each inclined arm 14 attaches to the inner member 11b via attachment points 602b (only one visible in this perspective).

Next, the central support (11a, 11b) is installed onto the foundation 601a (block 603). The central support (11a, 11b) is shown installed on the foundation 601a in FIG. 6E. In some implementations, the central support (11a, 11b) includes alignment markings that align with alignment markings on the foundation 601a to indicate the direction to true south. In some implementations, the central support (11a, 11b) is leveled and plumbed, and secured to the structural bolts (601b of FIG. 6C) using flat washers and structural nuts.

Next, to permit rotation of the inner member 11b relative to the outer member 11a, the gearbox 604a is aligned and installed (block 604).

In some implementations, the support frame 15 is provided in two sections. In such implementations, the two sections must be assembled (block 605). FIG. 6F illustrates a support frame 15 consisting of two sections (605a and 605b) which have been assembled.

Next, the support frame 15 is mounted to the cross member 14 (block 606). As illustrated in FIG. 6G, the cross member is coupled to the parallel members 150b (see FIG. 1B) of the support frame 15 at mounting points 606a and 606c. The mounting points can include, e.g., a nut and bolt combination.

To facilitate tilting the solar array at various angles, a jackscrew is installed (block 607). As shown in FIG. 6G, the jackscrew 607a is coupled to the cross member 14 and the support frame 15. The jackscrew 607a couples to the support frame 15 via attachment point 607b. In this implementation, attachment point 607b includes a generally cylindrical member that allows the angle of the support frame 15 to change as the jackscrew 607a translates in a generally vertical direction.

Next, the subarrays (e.g., item 16) are installed on the support frame 15 (block 608). Installation can utilize, for example, structural bolts that pass through the support frame and couple to each subarray 16. In some implementations, to facilitate installations of the subarrays, the jackscrew 607a is adjusted such that the frame 15 is substantially horizontally aligned (e.g., within ±5 degrees) with the mounting surface of the foundation 601a. FIG. 6H illustrates a schematic of the array 10 including subarrays 16, each of which is assigned an index numeral one through ten. The table of FIG. 6H illustrates an implementation of the order in which each array 16 can be installed to maintain balance of the structure. As shown, installation begins with array five, and then proceeds in sequence to array six, array four, array seven, array three, array eight, array two, array nine, array one and array ten. In another implementation, installation begins with array six, and then proceeds in sequence to five, seven, four, eight, three, nine, two, ten and one.

While the blocks of FIG. 6A are presented in a particular order, that order is not essential. Moreover, additional blocks may occur between, before, or after the blocks presented. For example, some implementations order the blocks in any of the following ways:

(a) 600, 601, 603, 602, 604, 605, 606, 607, 608

(b) 600, 601, 602, 604, 603, 605, 606, 607, 608

(c) 605, 600, 601, 602, 603, 604, 606, 607, 608

(d) 600, 605, 601, 602, 603, 604, 606, 607, 608

(e) 600, 601, 603, 604, 602, 605, 606, 607, 608.

Accordingly, other implementations are within the scope of the claims.

What is claimed is:

1. A method of assembling a sun-tracking concentrator photovoltaic solar cell array system for producing energy from the sun, the system comprising a central support having a stationary first member and second member, and a first, base end of the second member mounted within the first member, the second member extending from the first member; the system further comprising a pair of inclined arms that extend respectively from the base end of the second member, a support frame carried by the pair of inclined arms and a cross member coupled to a second, opposing end of the second member, the support frame being rotatable with respect to the central support; the system further comprising a jackscrew coupled to the cross member and the support frame, a first actuator arranged to rotate the jackscrew, and a generally rectangular planar solar cell array including a plurality of subarrays of triple junction III-V semiconductor compound concentrator solar cell receivers mounted on the support frame and a second actuator for rotating the central support and the support frame, the method comprising:
installing a cement foundation on a surface of the earth;
installing the central support by mounting the first member substantially perpendicular to the cement foundation and installing the second actuator so as to facilitate the second member to rotate relative to the first member thereby allowing the solar cell array to track the sun;
coupling the cross member to the central support;
coupling the pair of inclined arms to the cross member and the central support to structurally support the cross member;
coupling the support frame to the cross member, the support frame comprising a first frame assembly arranged to couple to one or more solar cell subarrays;
coupling one or more solar cell subarrays to the first frame assembly thereby forming the solar cell array; and
installing the jackscrew and the first actuator so as to facilitate adjusting the inclination of the solar cell array relative to the surface of the earth and thereby track the sun.

2. The method of claim 1 further comprising providing a second frame assembly coupled orthogonally to the first frame assembly, the second frame assembly arranged to increase the rigidity of the first frame assembly.

3. The method of claim 2 wherein the second frame assembly comprises a truss.

4. The method of claim 2 wherein the solar cell subarrays are coupled to the first frame assembly such that the second frame assembly is mounted above the vertical center of the solar cell array.

5. The method of claim 1 wherein coupling the cross member to the central support occurs before coupling the cross member to the foundation.

6. The method of claim 1 wherein the support frame is provided in two halves, the method comprising:
assembling the two halves of the support frame.

7. The method of claim 1 wherein the first frame assembly is coupled such that it is arranged along the greatest perpendicular dimension of the solar cell array.

8. The method of claim 2 wherein the second frame assembly is coupled such that it is arranged along the greatest perpendicular dimension of the solar cell array.

9. The method of claim 1 wherein the first frame assembly comprises ten mounting positions, each arranged to receive a solar cell subarray.

10. The method of claim 9 wherein the ten mounting positions are sequentially ordered from one end of the first frame assembly to the opposite end of the first frame assembly, and wherein coupling the solar cell subarrays to the first frame assembly comprising:
installing a first solar cell subarray at a fifth mounting position and installing a second solar cell subarray at a sixth mounting position;
and subsequently installing a third solar cell subarray at a fourth mounting position and installing a fourth solar cell subarray at a seventh mounting position;
and subsequently installing a fifth solar cell subarray at a third mounting position and installing a sixth solar cell subarray at an eighth mounting position;
and subsequently installing a seventh solar cell subarray at a second mounting position and installing an eighth solar cell subarray at a ninth mounting position;
and subsequently installing a ninth solar cell subarray at a first mounting position and installing a tenth solar cell subarray at a tenth mounting position.
